(19) United States
(12) Patent Application Publication
(10) Pub. No.: US 2006/0019447 A1
(43) Pub. Date: Jan. 26, 2006

(54) Process for the self-aligning production of a transistor with a U-shaped gate

(76) Inventors: Martin Gutsche, Dorfen (DE); Harald Seidl, Poering (DE)

Correspondence Address: JENKINS, WILSON & TAYLOR, P. A., 3100 TOWER BLVD, SUITE 1400, DURHAM, NC, 27707, US

(21) Appl. No.: 11/185,584

(22) Filed: Jul. 20, 2005

(30) Foreign Application Priority Data
Jul. 20, 2004 (DE) 102004035108.2

(51) Int. Cl. H01L 21/336; H01L 21/338

(52) U.S. Cl. 438/270; 438/183

(57) ABSTRACT

The present invention provides a process for producing a gate element for a transistor, in which a substrate (101) is provided, an insulation layer (104) and a sacrificial layer (105) are deposited on the substrate (101), the sacrificial layer (105) is patterned and a spacing layer (107) is deposited on the sacrificial layer, the spaces in the patterned sacrificial layer (105) are filled with a filling layer (108), the sacrificial layer structure (105a, 105b) and regions of the insulation layer (104) which are located beneath the sacrificial layer structure (105a, 105b) are removed. Finally, recesses (110) are etched into the substrate (101), the spacing layer (107) and those regions of the insulation layer which are not covered by the filling layer (108) are removed, a gate oxide layer (111) of the gate element is deposited and a gate electrode layer (112) of the gate element is deposited in the recesses (110). After the filling layer (108) has been removed, the result is a gate element for a field effect transistor with a low leakage current which can advantageously be used as a select transistor for a memory cell of a memory cell array.

The present invention relates in general terms to memory devices for the storage of data, and relates in particular to a select transistor which is provided for a memory cell of the memory device and has a U-shaped gate element.

Specifically, the present invention relates to a process for producing the gate element for a transistor, in which a substrate is provided, the substrate having an active substrate region enclosed by isolation elements, an insulation layer and a sacrificial layer being deposited on the substrate and the sacrificial layer being patterned by means of lithographic processes. The process provides for recesses to be etched into the substrate after specific regions of sacrificial layer structures have been uncovered. A gate oxide layer of the gate element is deposited in the recesses, and then a gate electrode layer of the gate element is deposited on the gate oxide layer of the gate element.

With an increasing integration density of memory devices, the lateral structures of transistors which are assigned to a memory cell of the memory device, i.e. what are known as select transistors, are becoming ever smaller.

Select transistors of this type are only permitted extremely low leakage currents, in order to keep the refresh cycle of the memory cells at a low level, i.e. it is necessary for the retention time of the memory cell to be made as long as possible. This retention time is disadvantageously reduced by leakage currents of the associated select transistor. With ever smaller dimensions, which currently involve a feature size of less than 100 nanometres (nm), it is becoming increasingly difficult to use planar MOS (Metal-Oxide-Silicon) transistors as select transistors for a memory cell, for example a DRAM cell (DRAM=Dynamic Random Access Memory), since the leakage currents of transistors of this type are too high, which means that the requirements with regard to data retention time can no longer be satisfied.

Conventional processes for producing transistors of this type are aimed at optimizing source/drain and body regions, in order thereby to improve the operating performance of the transistors with regard to the data retention time. Furthermore, it has been proposed to use three-dimensional transistors, as disclosed, for example, in the publications: “Goebel et al., Fully depleted surrounding gate transistor (SGT) for 70 nm and beyond, IEDM (2002), page 275”; “D.-H. Lee et al., Fin-Channel-Array Transistor (FCAT) featuring sub-70 nm low power and high performance DRAM, IEDM (2003), page 407”; and “H. S. Kim et al., An outstanding and highly manufacturable 80 nm DRAM technology, IEDM (2003), page 411”.

In the case of what is known as a recess channel array transistor, which is described in the last one of the three publications mentioned above, a U-shaped channel region of a field-effect transistor and the gate element of the transistor are produced using two separate lithography steps. This results in the significant drawback that misalignments may occur between the different lithography steps, which has a highly adverse effect on the operating performance of the finished transistor. Furthermore, if the misalignment occurs, it is difficult to control/monitor the critical dimensions.

A further problem is that in the event of a misalignment of the gate element of a field-effect transistor with respect to the other elements, for example with respect to the source and drain regions, a defective field-effect transistor is formed, which does not satisfy the specifications. In particular, a field-effect transistor of this type, formed with a misaligned gate element, does not satisfy the specifications with respect to leakage current properties, i.e. the leakage currents become too high, in such a manner that when this transistor is used as a select transistor for a DRAM memory cell (DRAM=Dynamic Random Access Memory), this cell then does not have a sufficient retention time.

Therefore, it is an object of the present invention to provide a transistor structure in which a misalignment is avoided and in which leakage currents are reduced.

According to the invention, this object is achieved by a process described in patent Claim 1.

Furthermore, the object is achieved by a process described in patent Claim 20.

Further configurations of the invention will emerge from the subclaims.

One main concept of the invention consists in the gate element of a field-effect transistor, i.e. of a recess channel array transistor, being formed in self-aligning fashion with respect to a U-shaped channel region. In this case, what is known as a dummy gate and a spacer technique are used in order for the gate element to be arranged in self-aligning fashion with respect to a U-shaped channel region. In this case, the above two auxiliary elements, i.e. the dummy gate and the spacer, serve merely as spacing elements.

According to a first aspect of the present invention, the process according to the invention substantially comprises the steps of:
a) providing a substrate, which has an active substrate region enclosed by isolation elements;
b) depositing an insulation layer on the substrate;
c) depositing a sacrificial layer on the insulation layer;
d) patterning the sacrificial layer which has been deposited on the insulation layer by means of lithography, in such a manner that predeterminable regions of the insulation layer are uncovered in order to obtain sacrificial layer structures;
e) depositing a spacing layer on the structure obtained in step d);
f) depositing a filling layer in the spaces between the sacrificial layer structures;
g) removing the sacrificial layer structures and the regions of the insulation layer which are located below the sacrificial layer structures;
h) etching recesses into the substrate in the regions of the substrate which are located beneath the sacrificial layer structures;
i) removing the spacing layer and those regions of the insulation layer which are not covered by the filling layer;
j) depositing a gate oxide layer of the gate element;
k) depositing a gate electrode layer of the gate element in the recesses; and
l) removing the filling layer.

According to a second aspect of the present invention, the process according to the invention substantially comprises the steps of:
a) providing a substrate, which has an active substrate region enclosed by isolation elements;
b) depositing an insulation layer on the substrate;
c) depositing a sacrificial layer on the insulation layer;
d) patterning the sacrificial layer which has been deposited on the insulation layer by means of lithography, in such a manner that predeterminable regions of the insulation layer are uncovered in order to obtain sacrificial layer structures;
e) depositing a filling layer in the spaces between the sacrificial layer structures;
f) removing the sacrificial layer structures;
   g) depositing a spacing layer on the structure obtained in step f);
h) removing uncovered regions of the insulation layer;
i) etching recesses into the substrate in those regions of the substrate which are located beneath the sacrificial layer structures;
j) removing the spacing layer;
k) depositing a gate oxide layer of the gate element in the uncovered regions of the filling layer;
l) depositing a gate electrode layer of the gate element in the recesses; and
m) removing the filling layer.

The subclaims give advantageous refinements and improvements of the associated subject matter of the invention.

According to a preferred refinement of the present invention, the substrate is provided as a silicon wafer. The silicon wafer has an active region which is delimited by isolation elements. The isolation elements are preferably provided in the form of a shallow trench structure by an STI (Shallow Trench Isolation) formation.

According to a further preferred refinement of the present invention, the insulation layer is in the form of an oxide layer. The insulation layer preferably consists of a silicon dioxide (SiO₂) material.

According to yet another preferred refinement of the present invention, the sacrificial layer which has been deposited on the insulation layer consists of a polysilicon material.

According to yet another preferred refinement of the present invention, the patterning of the sacrificial layer which has been deposited on the insulation layer by means of lithography in such a manner that predeterminable regions of the insulation layer are uncovered is carried out in such a manner that a mask layer which has been applied to the sacrificial layer is removed at the predetermined regions, and that the sacrificial layer is etched in these regions.

According to yet another preferred refinement of the present invention, the patterning of the sacrificial layer which has been deposited on the insulation layer by means of lithography in such a manner that predeterminable regions of the insulation layer are uncovered in order to obtain sacrificial layer structures is carried out by means of an etch which is selective with respect to the insulation layer.

According to yet another preferred refinement of the present invention, the deposition of the spacing layer is carried out by means of chemical vapour deposition (CVD).

According to yet another preferred refinement of the present invention, the spacing layer is provided in the form of a carbon material, a silicon oxide (SiO₂) material or a silicon nitride (Si₃N₄) material.

According to yet another preferred refinement of the present invention, the spacing layer is etched anisotropically, selectively with respect to the sacrificial layer and with respect to the insulation layer.

According to yet another preferred refinement of the present invention, the spacing layer is etched selectively with respect to the sacrificial layer and with respect to the insulation layer, in such a manner that the spacing layer remains only on the lateral surfaces of the sacrificial layer structures.

It is advantageous for the filling layer to be provided in the form of a silicon nitride (Si₃N₄) material.

According to yet another preferred refinement of the present invention, the filling layer is planarized in such a manner that the sacrificial layer structures and the filling layer form a planar surface. It is expedient for the filling layer to be planarized in such a manner that the sacrificial layer structures and the filling layer are levelled by means of chemical mechanical polishing.

According to yet another preferred refinement of the present invention, the spacing layer is removed by means of an isotropic etch in an oxygen plasma.

According to yet another preferred refinement of the present invention, the etching of recesses into the substrate in the regions of the substrate located beneath the sacrificial layer structures—following removal of the sacrificial layer structures—is carried out by means of an anisotropic etching process.

It is advantageous for the gate oxide layer of a gate element which forms the field-effect transistor to be deposited by means of thermal oxidation and/or by means of oxidation with oxygen radicals.

It is preferable for the gate electrode layer of the gate element for a field-effect transistor, following deposition in the recesses, to be planarized by means of chemical mechanical polishing.

According to yet another preferred refinement of the present invention, the sacrificial layer is removed selectively with respect to the filling layer and the insulation layer by means of plasma etching or a wet-chemical route.

According to yet another preferred refinement of the present invention, the planarizing of the filling layer in such a manner that the sacrificial layer structures and the filling layer form a planar surface is carried out by means of chemical mechanical polishing (CMP) which stops at the sacrificial layer.

According to the above-described aspects of the present invention, it is possible to deposit a gate element of a field-effect transistor in a self-aligning manner in a recess while avoiding misalignments. The leakage currents of a field-effect transistor which is designed as a select transistor for a memory cell and has a gate element of this type are advantageously reduced.

Exemplary embodiments of the invention are illustrated in the drawings and explained in more detail in the description which follows.

In the drawings:

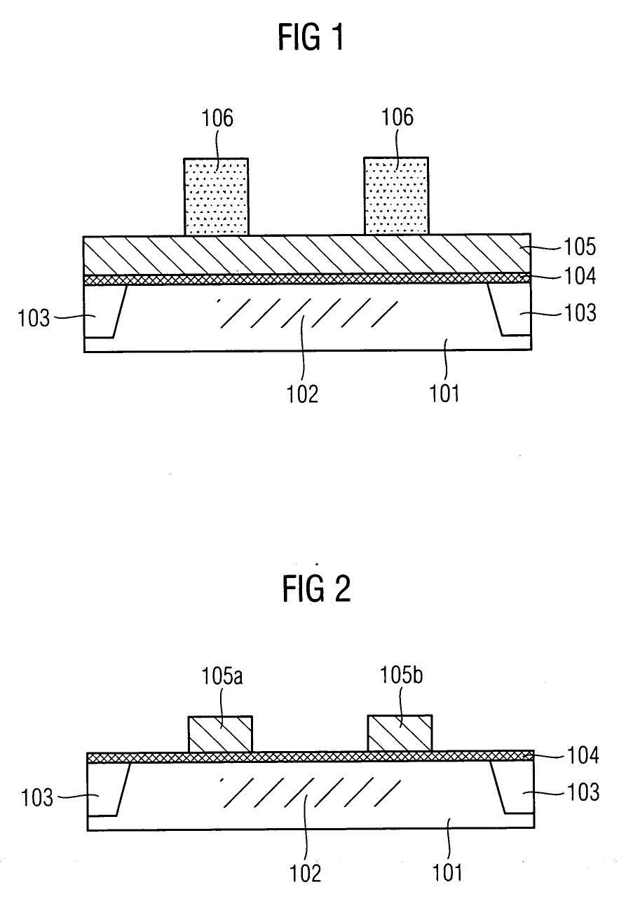

FIG. 1 shows a substrate with applied insulation layer and sacrificial layer and patterned mask layer, in accordance with a first aspect of the present invention;

FIG. 2 shows the structure shown in FIG. 1 with the sacrificial layer having been partially etched;

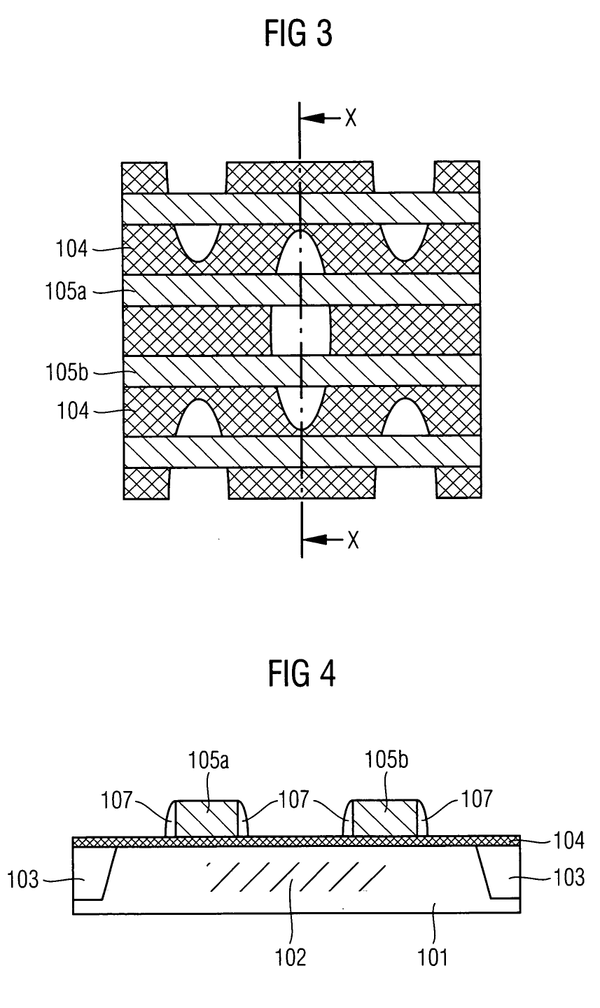

FIG. 3 shows a plan view, in which FIG. 2 corresponds to a section X-X;

FIG. 4 shows the structure shown in FIG. 2 following deposition of a spacing layer;

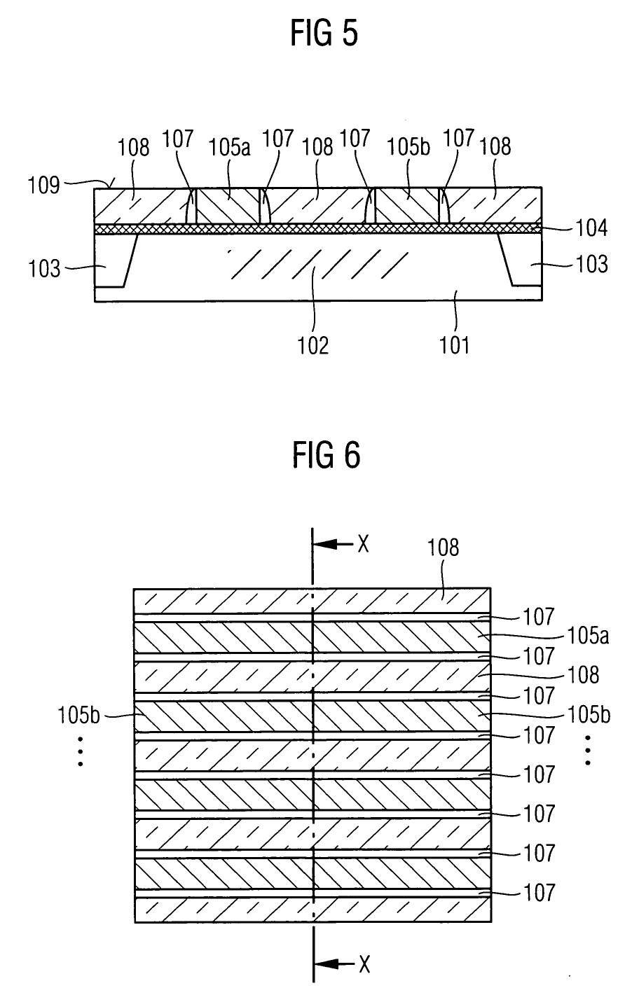

FIG. 5 shows the structure shown in FIG. 4 following deposition of a filling layer;

FIG. 6 shows a plan view of the structure illustrated in FIG. 5, in which FIG. 5 represents a section X-X through FIG. 6;

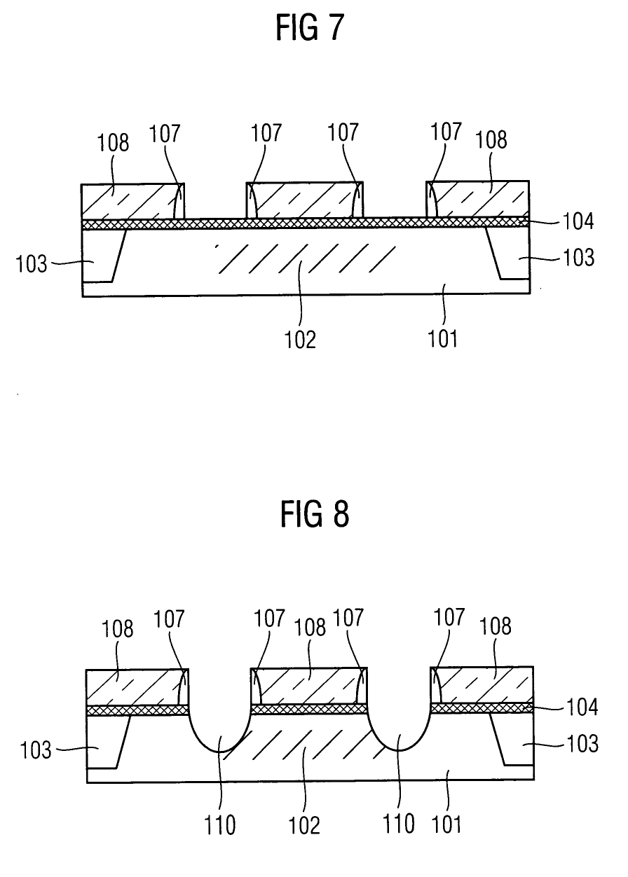

FIG. 7 shows the structure illustrated in FIG. 5 after removal of sacrificial layer structures;

FIG. 8 shows the structure shown in FIG. 7 after etching of the insulation layer and of recesses into the substrate;

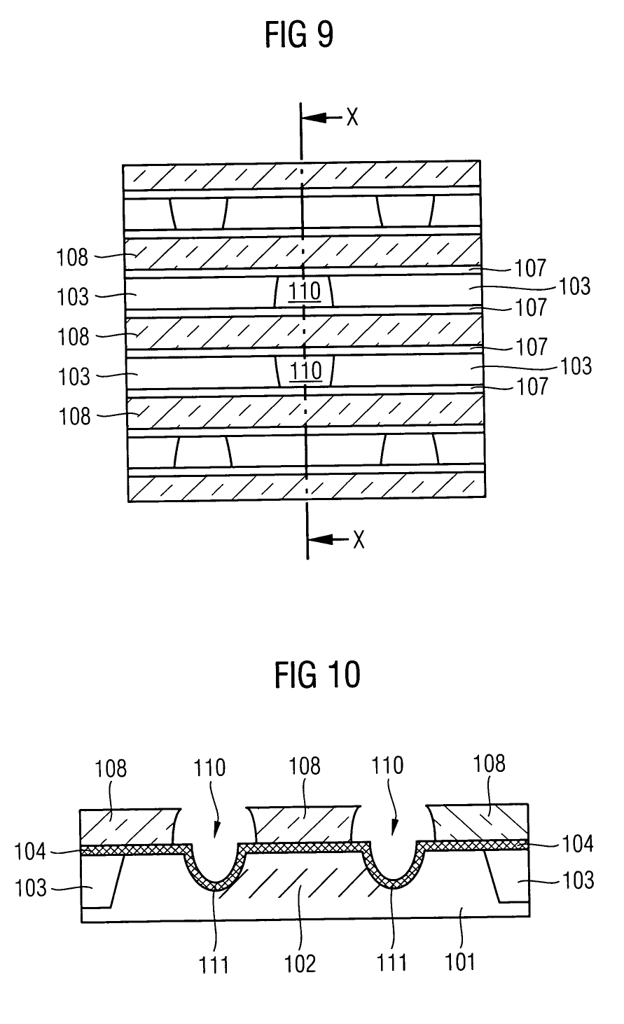

FIG. 9 shows a plan view of the structure illustrated in FIG. 8, in which FIG. 8 corresponds to a section X-X through FIG. 9;

FIG. 10 shows the structure illustrated in FIG. 8 following application of a gate oxide layer in the recesses;

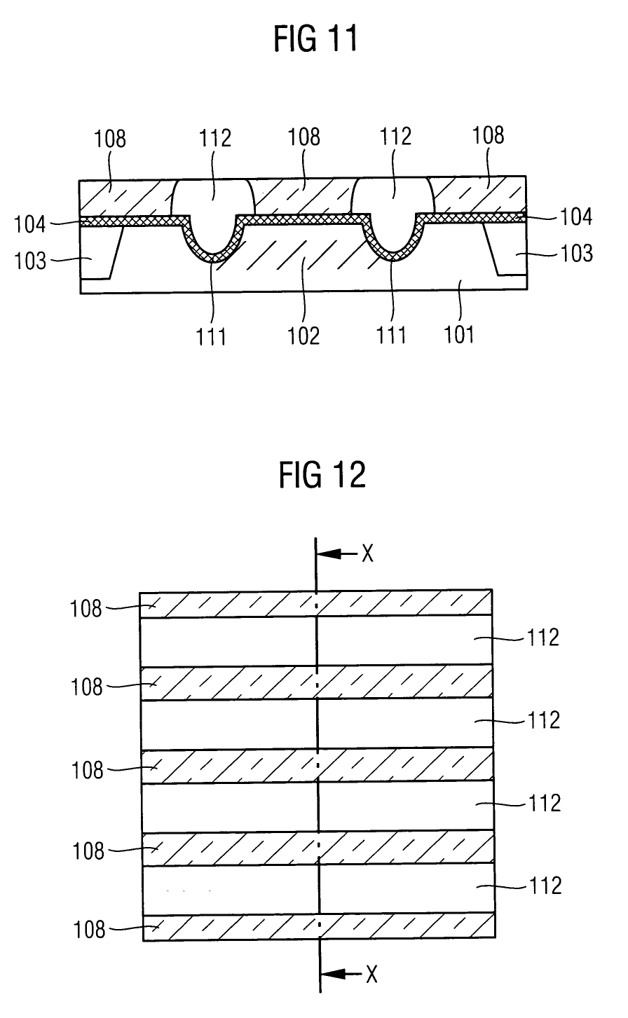

FIG. 11 shows the structure shown in FIG. 10 after deposition of a gate electrode layer in the recesses;

FIG. 12 shows a plan view of the structure shown in FIG. 11, in which the sectional view illustrated in FIG. 11 corresponds to a section X-X through FIG. 12;

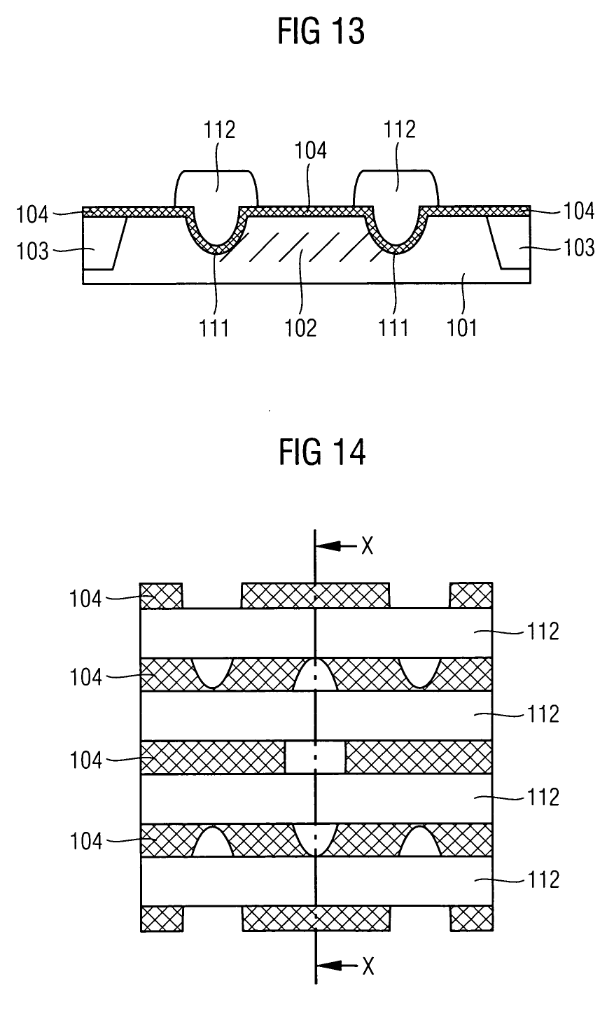

FIG. 13 shows the structure illustrated in FIG. 11 following removal of the filling layer regions;

FIG. 14 shows a plan view of the structure illustrated in FIG. 13, in which the cross section of the structure shown in FIG. 13 corresponds to a section X-X through FIG. 14;

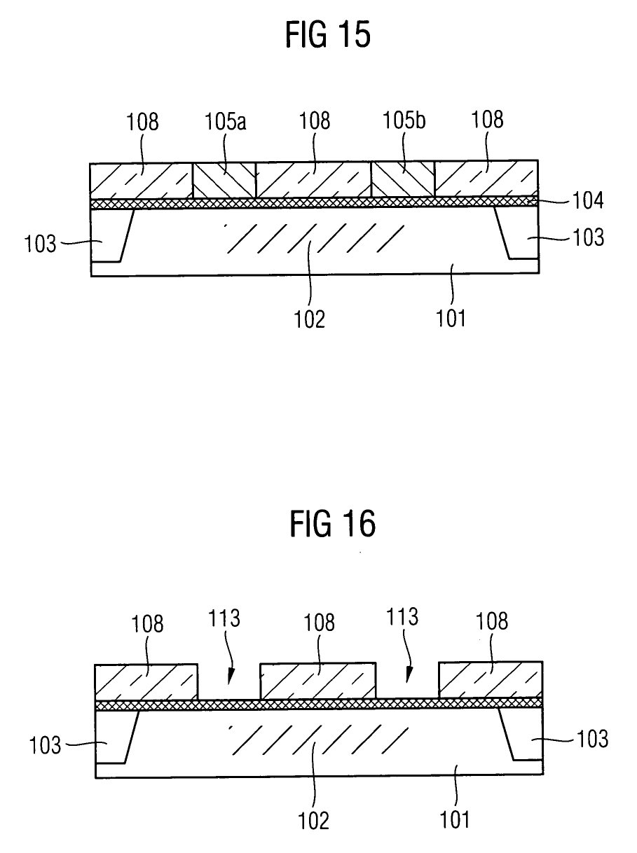

FIG. 15 shows a substrate with an insulation layer and sacrificial layer structures applied to the insulation layer, the spaces between which sacrificial layer structures have been filled by a filling layer, in accordance with a second aspect of the present invention;

FIG. 16 shows the structure illustrated in FIG. 15 with the sacrificial layer structures having been removed;

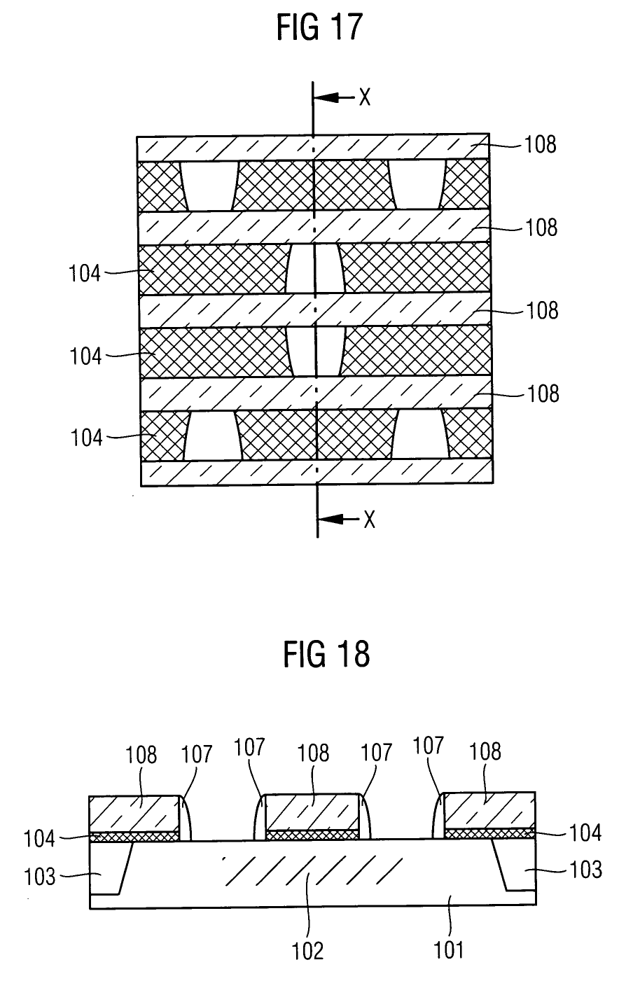

FIG. 17 shows a plan view of the structure illustrated in FIG. 16, in which the sectional view shown in FIG. 16 corresponds to section X-X through FIG. 17;

FIG. 18 shows the structure illustrated in FIG. 16, with a spacing layer having been applied to the side faces of the filling layer;

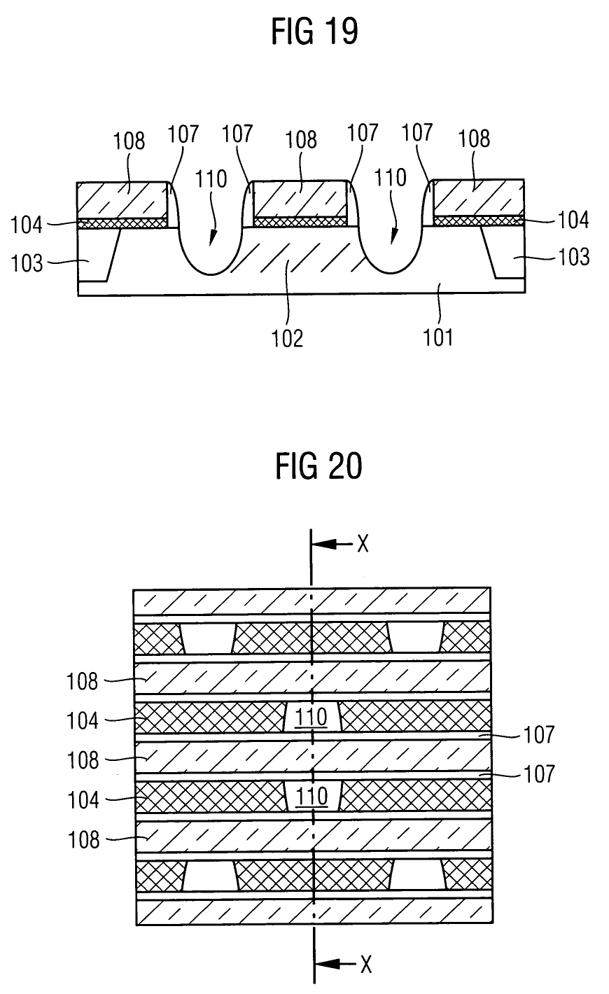

FIG. 19 shows the structure illustrated in FIG. 8, with recesses having been etched anisotropically into the substrate;

FIG. 20 shows a plan view of the structure illustrated in FIG. 19, with the sectional view shown in FIG. 19 corresponding to a section X-X through FIG. 20;

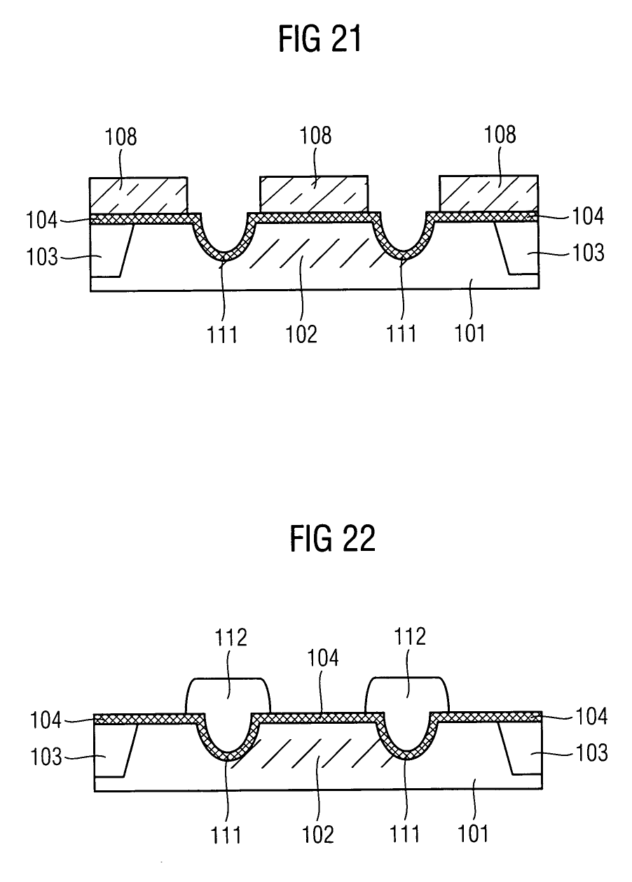

FIG. 21 shows the structure illustrated in FIG. 19 after deposition of a gate oxide layer;

FIG. 22 shows the structure illustrated in FIG. 21 after application of a gate electrode layer and removal of the filling layer; and

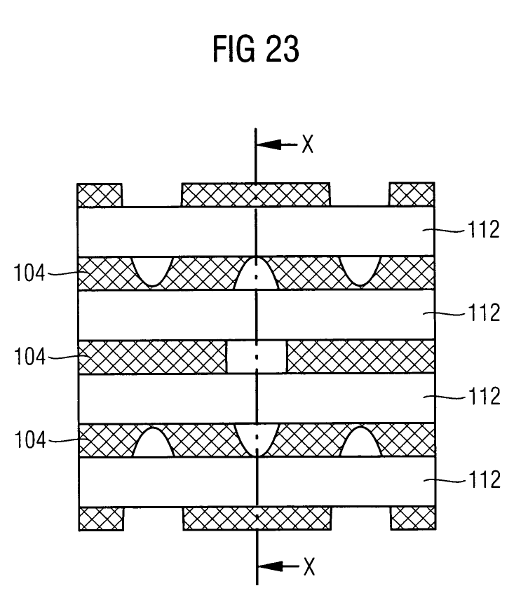

FIG. 23 shows a plan view of the structure illustrated in FIG. 22, in which the sectional view shown in FIG. 22 corresponds to a section X-X through FIG. 23.

In the figures, identical designations denote identical or functionally equivalent components or steps.

The text which follows, with reference to FIGS. 1 to 14, describes a first aspect of the process according to the invention for producing a gate element for a transistor.

As illustrated in FIG. 1, a substrate 101 with an active region 102 formed therein is provided. The active region 102 is delimited by isolation elements 103. The isolation elements 103 are provided, for example, as an STI (Shallow Trench Isolation) structure. As shown in FIG. 1, an insulation layer 104, which is preferably formed from a silicon dioxide (SiO₂) material, has been deposited on the structure formed by an active region 102 and the substrate 101 with the isolation elements 103. Furthermore, a sacrificial layer 105, for example an electrically conductive layer, which is denoted by reference numeral 105 in FIG. 1, has been deposited on the insulation layer 103.

Furthermore, FIG. 1 illustrates a patterned resist layer or mask layer 106 as is customarily used in lithographic processes for the patterning of regions below it. The person skilled in the art will be aware how a mask layer 106 of this type is patterned by means of lithography, and consequently the lithography process is not described in further detail in the text which follows.

FIG. 2 shows the structure illustrated in FIG. 1 after etching of the sacrificial layer 105 at the regions which are left uncovered by the mask layer 106, with an etch of the sacrificial layer 105 having been carried out selectively with respect to the insulation layer 104, in such a manner that the etch stops at the insulation layer 104. Furthermore, the mask layer 106 on the sacrificial layer was removed in the process step illustrated in FIG. 2. The remaining regions of the sacrificial layer are denoted by reference numerals 105a and 105b and are referred to as sacrificial layer structures in the text which follows.

FIG. 3 shows a plan view of the structure illustrated in FIG. 2, in which the sectional view shown in FIG. 2 corresponds to a section X-X through FIG. 3. The plan view reveals the sacrificial layer structures 105a and 105b as well as the uncovered region of the insulation layer 104.

FIG. 4 shows the structure illustrated in FIG. 2 after application of a spacing layer 107 according to the invention; a process of this type is also referred to as a spacer technique. The spacing parts 107 serve purely as spacers and assist with self-alignment of the gate element of the field-effect transistor which is to be formed with respect to the other components.

It should be noted that the spacing layer 107 is required in particular at the side faces of the sacrificial layer structures. To achieve this, after the spacing layer 107 has been deposited, the spacing layer is subjected to an anisotropic etch, in such a manner that those parts of the spacing layer 107 which have been deposited on the insulation layer 104 (not shown in FIG. 4) are removed. Slight rounding of the spacing layer 107 in the upper region of the side wall of the sacrificial layer structures 105a, 105b is caused by an anisotropic etching process of this nature.

FIG. 5 shows the structure illustrated in FIG. 4 after a process of filling the spaces with a filling layer 108. Whereas the sacrificial layer structures 105a, 105b are formed, for example, from a polysilicon material, the filling layer 108 is preferably formed from a silicon nitride (Si₃N₄) material. FIG. 6 shows the structure illustrated in FIG. 5 in the form of a plan view, in which FIG. 5 as a sectional view corresponds to a section X-X through FIG. 6. FIG. 6 now reveals regions of the spacing layer 107 alternating with patterned regions 105a, 105b of the original sacrificial layer 105. The plan view shown in FIG. 6 also reveals the filling layer 108, which has preferably been provided by means of chemical mechanical polishing stopping at the sacrificial layer structures 105a, 105b.

FIG. 7 shows the structure illustrated in FIG. 5 after the regions of the sacrificial layer 105 located between the filling layer 108 and the spacing layer 107, i.e. the sacrificial layer structures 105a, 105b, have been removed again. It should be noted that both the spacing layer 107 and the remaining regions of the sacrificial layer structures 105a, 105b serve only as spacers and according to the invention allow self-alignment of the gate element with respect to other elements. Consequently, the respective sacrificial layer structure 105a, 105b can also be referred to as a dummy gate.

To form a recess channel array transistor, i.e. a transistor with a U-shaped channel region, it is now necessary for recesses to be etched into the substrate, for example in a U shape. For this purpose, first of all, as shown in the process step illustrated in FIG. 8, the insulation layer 104 is removed in the uncovered region, selectively with respect to the spacing layer 107, for example by an anisotropic etch.

Then, recesses 110 which are in U shape are etched selectively with respect to the material of the filling layer 108, for example selectively with respect to silicon nitride (Si₃N₄) or carbon (C). FIG. 8 shows a cross section through the structure which is formed, whereas FIG. 9 shows a plan view of the structure illustrated in FIG. 8, revealing a plan view of the recesses where FIG. 8 represents a section on line X-X through FIG. 9. Also visible are the remaining isolation elements 103 and the regions of the spacing layer 107 and the filling layer 108. In a subsequent process step, as shown in FIG. 10, the spacing layer 107, which served only as a spacer, is removed, resulting in a symmetrically widened region with respect to each of the recesses 110.

Furthermore, as shown in FIG. 10, a gate oxide layer 111 is deposited in the uncovered regions. The gate oxide layer 111 merges into the insulation layer 104 which has previously been deposited and was described with reference to FIG. 1. The gate oxide layer forms the gate oxide of the field-effect transistor that is to be formed. It is preferable for the deposition of the gate oxide layer 111 of the gate element to be carried out by means of thermal oxidation and/or by means of oxidation using oxygen radicals.

After the deposition of the gate oxide layer 111 in the uncovered regions, a gate electrode layer 112 is deposited in the uncovered regions, as illustrated in FIG. 11. The upper surface of the gate electrode layer 112 ends flush with the upper surface of the filling layer 108. It is preferable for the entire surface to be planarized by means of chemical mechanical polishing (CMP) after the gate electrode layer 112 has been deposited in the recesses 110.

FIG. 12 shows a plan view of the structure illustrated in FIG. 11, in which FIG. 11 corresponds to a section on line X-X through FIG. 12.

In a final process step, which relates to the production of the gate element, finally, the filling layer 108 is removed selectively with respect to the electrode layer 112. Removal of the filling layer in this way, if the filling layer 108 has been formed from a silicon nitride (Si₃N₄) material, can be carried out with the aid of H₃PO₄.

FIG. 13 shows the resulting structure after removal of the filling layer, ensuring that the gate element is built up in a self-aligning manner. It is thus possible to reduce leakage currents, with the result that the data retention time of the memory cell of a memory device associated with the field-effect transistor which is to be formed is increased.

FIG. 14 shows a plan view of the structure shown as a cross-sectional view in FIG. 13, the cross section illustrated in FIG. 13 having been taken on line X-X through FIG. 14.

It should be noted that the recesses 110 which are formed in a U shape have a typical depth of 100-200 nm (nanometres) and a diameter of typically 90 nm (nanometres) or less.

A process for producing a gate element for a transistor in accordance with a second aspect of the present invention will now be described with reference to FIGS. 15 to 23.

It should be noted that throughout the figures identical designations denote identical or functionally equivalent components or steps. Therefore, to prevent repetition in the description, some of the components or steps which have already been described above with reference to the first aspect of the present invention are not explained once again.

The process for producing a gate element in accordance with the second aspect of the present invention is based on the provision of a patterned sacrificial layer 105, in such a manner as to form sacrificial layer structures 105a, 105b as explained above with reference to FIGS. 1 to 3. FIG. 15 now shows a process step which replaces the process step shown in FIG. 4 with reference to the first aspect of the present invention.

As shown in FIG. 15, after the sacrificial layer structures 105a, 105b have been provided on the insulation layer 104 (cf. FIG. 2 and FIG. 3), first of all a filling layer 108 is introduced into the spaces between the sacrificial layer structures 105a, 105b. After the sacrificial layer structures 105a, 105b have been etched selectively with respect to the material of the filling layer 108, uncovered regions 113 are formed, as illustrated in FIG. 16. FIG. 17 shows a plan view of the structure shown in FIG. 16, in which FIG. 16 corresponds to a cross-sectional view on line X-X through FIG. 17.

FIG. 18 shows the structure illustrated in FIG. 16 after deposition of a spacing layer 107 at the side faces of the filling layer 108. FIG. 18 also shows that the uncovered regions of the insulation layer 104 have been removed.

FIG. 19 shows the structure illustrated in FIG. 18 after recesses 110 have been etched into the substrate 101 by means of an anisotropic etching process. This results in self-aligning formation of the, for example, U-shaped recesses symmetrically with respect to those parts of the spacing layer 107 which cover the lateral surfaces of the structures of the filling layer 108. FIG. 20 shows the structure illustrated in FIG. 19 in the form of a plan view, in which the section shown in FIG. 19 is taken on line X-X through FIG. 20.

In the following process steps, the result of which is shown in FIG. 21, the spacing layer 107, which like the sacrificial layer structures 105a, 105b served only as a spacer, is etched so as to be removed. Furthermore, a gate oxide layer 111 has been applied in the uncovered regions, as shown in FIG. 21. The gate oxide layer 111 merges into the insulation layer 104 which has already been described above with reference to FIGS. 1 and 2 and forms the gate oxide of the field-effect transistor to be produced.

FIG. 22 shows the structure illustrated in FIG. 21 following further process steps which have been carried out on the structure shown in FIG. 21. After deposition of the gate oxide layer 111, first of all a gate electrode layer 112 is deposited in the uncovered regions, in such a manner that the surface of the gate electrode layer 112 ends approximately flush with the surface of the filling layer 108.

As described above with reference to the first aspect of the present invention, the gate electrode layer 112 is now planarized so as to be planar with respect to the filling layer 108 by means of chemical mechanical polishing (CMP). Furthermore, to reach the state shown in FIG. 22, the filling layer 108 is finally removed. If the filling layer is formed, for example, as described above, from a silicon nitride (Si₃N₄) material, it is possible to provide for the filling layer to be removed by means of an H₃PO₄ process.

FIG. 23 shows a plan view of the gate element according to the invention illustrated as a sectional view in FIG. 22. The sectional view shown in FIG. 22 corresponds to a section on line X-X through FIG. 23.

It should be noted that in this way a self-aligning formation of the gate element is achieved. The spacing layer 107 serves inter alia to offset the source/drain regions of a field-effect transistor to be produced from the gate element.

Although the present invention has been described above on the basis of preferred exemplary embodiments, it is not restricted to these embodiments, but rather can be modified in numerous ways.

Also, the invention is not restricted to the possible applications mentioned.

### LIST OF DESIGNATIONS

In the figures, identical designations denote identical or functionally equivalent components or steps.
101 Substrate
102 Active substrate region
103 Isolation element
104 Insulation layer
105 Sacrificial layer
105a, Sacrificial layer structures
105b
106 Mask layer
107 Spacing layer
108 Filling layer
109 Planar surface
110 Recess
111 Gate oxide layer
112 Gate electrode layer
113 Uncovered regions

1. Process for producing a gate element for a transistor, comprising the steps of:
a) providing a substrate, which has an active substrate region enclosed by isolation elements;
b) depositing an insulation layer on the substrate;
c) depositing a sacrificial layer on the insulation layer;
d) patterning the sacrificial layer which has been deposited on the insulation layer by means of lithography, in such a manner that predeterminable regions of the insulation layer are uncovered in order to obtain sacrificial layer structures;
e) depositing a spacing layer on the structure obtained in step d);
f) depositing a filling layer in spaces between the sacrificial layer structures;
g) removing the sacrificial layer structures and the regions of the insulation layer which are located below the sacrificial layer structures;
h) etching recesses into the substrate in the regions of the substrate which are located beneath the sacrificial layer structures;
i) removing the spacing layer and those regions of the insulation layer which are not covered by the filling layer;
j) depositing a gate oxide layer of the gate element in the uncovered regions of the filling layer;
k) depositing a gate electrode layer of the gate element in the recesses; and
l) removing the filling layer.

2. Process according to claim 1, wherein the substrate is provided by a silicon wafer.

3. Process according to claim 1, wherein the isolation elements are formed by a shallow trench structure.

4. Process according to claim 1, wherein the insulation layer is provided in the form of an oxide layer.

5. Process according to claim 4, wherein the insulation layer provided in the form of an oxide layer consists of a silicon dioxide material.

6. Process according to claim 1, wherein the sacrificial layer deposited on the insulation layer consists of a polysilicon material.

7. Process according to claim 1, wherein the patterning of the sacrificial layer which has been deposited on the insulation layer by means of lithography in such a manner that predeterminable regions of the insulation layer are uncovered is carried out in such a manner that a mask layer which has been applied to the sacrificial layer is removed at the predetermined regions, and that the sacrificial layer is etched in these regions.

8. Process according to claim 1 wherein the patterning of the sacrificial layer which has been deposited on the insulation layer by means of lithography in such a manner that predeterminable regions of the insulation layer are uncovered in order to obtain sacrificial layer structures is carried out by means of an etch which is selective with respect to the insulation layer.

9. Process according to claim 1, wherein the deposition of the spacing layer on the structure obtained in step d) is carried out by means of chemical vapour deposition.

10. Process according to claim 1, wherein the spacing layer which is deposited on the structure obtained in step d) is provided from a carbon material.

11. Process according to claim 1 wherein the spacing layer which is deposited on the structure obtained in step d) is etched anisotropically, selective with respect to the sacrificial layer and with respect to the insulation layer.

12. Process according to claim 11, wherein the spacing layer which is deposited on the structure obtained in step d) is etched selectively with respect to the sacrificial layer and with respect to the insulation layer, in such a manner that the spacing layer remains in place only on the lateral surfaces of the sacrificial layer structures.

13. Process according to claim 1, wherein the filling layer is provided from a silicon nitride material.

14. Process according to claim 1 wherein the filling layer is planarized in such a manner that the sacrificial layer structures and the filling layer form a planar surface.

15. Process according to claim 14, wherein planarization of the filling layer in such manner that the sacrificial layer structures and the filling layer form a planar surface is carried out by means of chemical mechanical polishing.

16. Process according to claim 1, wherein the spacing layer is removed by means of an isotropic etch in an oxygen plasma.

17. Process according to claim 1, wherein the etching of recesses into the substrate in those regions of the substrate which are located beneath the sacrificial layer structures is carried out by means of an anisotropic etching process.

18. Process according to claim 1, wherein the deposition of the gate oxide layer of the gate element is carried out by means of thermal oxidation and/or by means of oxidation with oxygen radicals.

19. Process according to claim 1, wherein the gate electrode layer, after it has been deposited in the recesses, is planarized by means of chemical mechanical polishing.

20. Process according to claim 1, wherein the sacrificial layer is removed selectively with respect to the filling layer and the insulation layer by means of plasma etching or a wet-chemical route.

21. Process according to claim 15, wherein the planarizing of the filling layer in such a manner that the sacrificial layer structures and the filling layer form a planar surface is carried out by means of chemical mechanical polishing which stops at the sacrificial layer.

22. Process for producing a gate element for a transistor, comprising the steps of:
a) providing a substrate, which has an active substrate region enclosed by isolation elements;
b) depositing an insulation layer on the substrate;
c) depositing a sacrificial layer on the insulation layer;
d) patterning the sacrificial layer which has been deposited on the insulation layer by means of lithography, in such a manner that predeterminable regions of the insulation layer are uncovered in order to obtain sacrificial layer structures;
e) depositing a filling layer in spaces between the sacrificial layer structures;
f) removing the sacrificial layer structures;
g) depositing a spacing layer on the structure obtained in step f);
h) removing uncovered regions of the insulation layer,
i) etching recesses into the substrate in those regions of the substrate which are located beneath the sacrificial layer structures;
j) removing the spacing layer;
k) depositing a gate oxide layer of the gate element in the uncovered regions of the filling layer;
l) depositing a gate electrode layer of the gate element in the recesses; and
m) removing the filling layer.

23. Process according to claim 22, wherein the substrate is provided by a silicon wafer.

24. Process according to claim 22, wherein the isolation elements are formed by a shallow trench structure.

25. Process according to claim 22, wherein the insulation layer is provided in the form of an oxide layer.

26. Process according to claim 25, wherein the insulation layer provided in the form of an oxide layer consists of a silicon dioxide material.

27. Process according to claim 22, wherein the sacrificial layer deposited on the insulation layer consists of a polysilicon material.

28. Process according to claim 22, wherein the patterning of the sacrificial layer which has been deposited on the insulation layer by means of lithography in such a manner that predeterminable regions of the insulation layer are uncovered is carried out in such a manner that a mask layer which has been applied to the sacrificial layer is removed at the predetermined regions, and that the sacrificial layer is etched in these regions.

29. Process according to claim 22, wherein the patterning of the sacrificial layer which has been deposited on the insulation layer by means of lithography in such a manner that predeterminable regions of the insulation layer are uncovered in order to obtain sacrificial layer structures is carried out by means of an etch which is selective with respect to the insulation layer.

30. Process according to claim 22, wherein the deposition of the spacing layer on the structure obtained in step f) is carried out by means of chemical vapour deposition.

31. Process according to claim 22, wherein the spacing layer which is deposited on the structure obtained in step f) is provided from a carbon material, a silicon oxide material or a silicon nitride material.

32. Process according to claim 22 wherein the spacing layer which is deposited on the structure obtained in step f) is etched anisotropically, selective with respect to the sacrificial layer and with respect to the insulation layer.

33. Process according to claim 32, wherein the spacing layer which is deposited on the structure obtained in step f) is etched selectively with respect to the sacrificial layer and with respect to the insulation layer, in such a manner that the spacing layer remains in place only on the lateral surfaces of the filling layer.

34. Process according to claim 22, wherein the filling layer is provided in the form of a silicon nitride material.

35. Process according to claim 22 wherein the filling layer is planarized in such a manner that the sacrificial layer structures and the filling layer form a planar surface.

36. Process according to claim 35, wherein planarization of the filling layer in such manner that the sacrificial layer structures and the filling layer form a planar surface is carried out by means of chemical mechanical polishing.

37. Process according to claim 22, wherein the spacing layer is removed by means of an isotropic etch in an oxygen plasma.

38. Process according to claim 22, wherein the etching of recesses into the substrate in those regions of the substrate which are located beneath the sacrificial layer structures is carried out by means of an anisotropic etching process.

39. Process according to claim 22, wherein the deposition of the gate oxide layer of the gate element is carried out by means of thermal oxidation and/or by means of oxidation with oxygen radicals.

40. Process according to claim 22, wherein the gate electrode layer, after it has been deposited in the recesses, is planarized by means of chemical mechanical polishing.

41. Process according to claim 22, wherein the sacrificial layer is removed selectively with respect to the filling layer and the insulation layer by means of plasma etching or a wet-chemical route.

42. Process according to claim 36, wherein the planarizing of the filling layer in such a manner that the sacrificial layer structures and the filling layer form a planar surface is carried out by means of chemical mechanical polishing which stops at the sacrificial layer.

43. Select transistor for a memory cell, produced by a process according to claim 1.
